(19) United States
(12) Patent Application Publication
(10) Pub. No.: US 2015/0305166 A1
(43) Pub. Date: Oct. 22, 2015

(54) LASER PATTERNING OF DUAL SIDED TRANSPARENT CONDUCTIVE FILMS

(71) Applicant: Carestream Health, Inc., Rochester, NY (US)

(72) Inventors: Andrew T. Fried, Woodbury, MN (US); Jeffrey P. Treptau, Lakeville, MN (US); Michael G. Steward, Woodbury, MN (US); Eric L. Granstrom, Andover, MN (US); Robert J. Monson, Roseville, MN (US); Kiarash Vakhshouri, Lompoc, CA (US)

(21) Appl. No.: 14/667,742

(22) Filed: Mar. 25, 2015

Related U.S. Application Data
(60) Provisional application No. 61/982,399, filed on Apr. 22, 2014.

(51) Int. Cl. H05K 3/10; B23K 26/00; H05K 1/09

(52) U.S. Cl. CPC H05K 3/105; H05K 1/097; B23K 26/0054; B23K 26/0066; B23K 26/009

(57) ABSTRACT

A method of patterning an unpatterned transparent conductive film, the unpatterned transparent conductive film comprising: a transparent substrate, a first conductive layer disposed on a first surface of the transparent substrate, and a second conductive layer disposed on a second surface of the transparent substrate, the first and second surfaces being disposed on two opposing sides of the unpatterned transparent conductive film, the first conductive layer comprising a first set of metal nanostructures, and the second conductive layer comprising a second set of metal nanostructures, the method comprising irradiating the first conductive layer with at least one first laser to form a patterned transparent conductive film, where the irradiation of the first conductive layer patterns the first conductive layer with a first pattern without also patterning the second conductive layer with the first pattern, and also where the unpatterned transparent conductive film and the patterned transparent conductive film both exhibit total visible light transmissions of at least about 90%.

### CROSS REFERENCE TO RELATED APPLICATIONS

This application claims the benefit of U.S. Provisional Application No. 61/982,399, filed Apr. 22, 2014, entitled “LASER PATTERNING OF DUAL SIDED TRANSPARENT CONDUCTIVE FILMS,” which is hereby incorporated by reference in its entirety.

### BACKGROUND

Currently, the touch panel market is dominated by Glass-Film-Film (GFF) design in which two layers of transparent conductive film (TCF) are patterned and laminated together to form a device. The disadvantages of this stack-up include: 1) the thickness of GFF based on the two layers of film and two layers of optically clear adhesive (OCA), and 2) the optical limitations in transmission and haze by having more layers.

Suitable Glass-Film (GF1) designs and flexible printed circuits (FPC) for GF1 designs appear difficult to achieve using ITO alternatives, such as anisotropic metal nanowires, because of the fine trace widths required (20-100 μm). The market is dominated by double-sided indium tin oxide (DITO). See, for example, U.S. Pat. No. 7,887,997 to Chou and U.S. Pat. No. 8,507,800 to Long et al. Double-sided thick-film integrated circuits are known. See, for example, EP 0109084 to Storno A/S. Double-sided circuit boards are known. See, for example, U.S. Pat. No. 6,889,432 to Naito et al.

When performing laser spiraling, radiation absorbers may be incorporated to reduce transmission of a laser beam through glass. See, for example, U.S. Pat. No. 4,065,656 to Brown et al. Layers can be made to optimize energy absorption by incorporating suitable dyes. See, for example, U.S. Pat. No. 5,895,581 to Grunwald.

### SUMMARY

In some embodiments, a method is disclosed comprising forming at least one pattern on a transparent conductive film comprising a substrate, a first conductive layer comprising a first set of metal nanostructures, and a second conductive layer comprising a second set of metal nanostructures, the first conductive layer and the second conductive layer being disposed on opposing sides of the substrate, wherein the transparent conductive film comprises at least one compound for reducing transmission of radiation from the first side to the second side or from the second side to the first side, and where forming the at least one pattern comprises irradiating the first conductive layer using at least one laser to form a first pattern on the first conductive layer without also forming the first pattern on the second conductive layer.

In some embodiments, the at least one laser is linearly polarized. In some embodiments, the at least one laser emits at least one laser beam having a pulse duration of less than 100 picoseconds. In some embodiments, the at least one laser emits at least one laser beam having a pulse duration of less than about 50 picoseconds. In some embodiments, the at least one laser emits at least one laser beam having a pulse duration of less than about 20 picoseconds.

In some embodiments, the first conductive layer is irradiated by a first laser having a first wavelength and the second conductive layer is irradiated by a second laser having a second wavelength, the first wavelength and the second wavelength being substantially the same. In some embodiments, the first conductive layer is irradiated by a first laser having a first wavelength and the second conductive layer is irradiated by a second laser having a second wavelength, the first wavelength and the second wavelength being substantially different. In some embodiments, the first conductive layer and the second conductive layer is irradiated by the same laser.

In some embodiments, the at least one laser emits a laser beam having an ultraviolet (UV) wavelength. In some embodiments, the at least one laser emits a laser beam having an ultraviolet wavelength of less than about 450 nm. In some embodiments, the at least one laser emits a laser beam having an ultraviolet wavelength between about 340 nm and 420 nm. In some embodiments, the at least one laser emits a laser beam having an ultraviolet wavelength of about 355 nm. In some embodiments, the first conductive layer and the second conductive layer are irradiated simultaneously.

In some embodiments, transmissivity of ultraviolet radiation through the transparent conductive film is less than 90%. In some embodiments, transmissivity of ultraviolet radiation through the transparent conductive film is less than 75%. In some embodiments, transmissivity of ultraviolet radiation through the transparent conductive film is less than 50%.

In some embodiments, the compound comprises an ultraviolet radiation compound for absorbing ultraviolet radiation. In some embodiments, the compound comprises an ultraviolet reflective compound for reflecting ultraviolet radiation. In some embodiments, the compound comprises an infrared radiation compound for absorbing infrared radiation. In some embodiments, the compound comprises an infrared reflective compound for reflecting infrared radiation.

In some embodiments, the substrate comprises the compound. In some embodiments, the first conductive layer comprises the compound. In some embodiments, the second conductive layer comprises the compound. In some embodiments, the transparent conductive film further comprises at least one first undercoat layer disposed on the first side of the substrate between the first conductive layer and the substrate and at least one second undercoat layer disposed on the second side of the substrate between the second conductive layer and the substrate. In some embodiments, either the first undercoat layer or the second undercoat layer comprises the compound. In some embodiments, both the first undercoat layer and the second undercoat layer comprise the compound. In some embodiments, the transparent conductive film comprises a first overcoat layer disposed on the first conductive layer and a second overcoat layer disposed on the second conductive layer, and wherein either the first overcoat layer or the second overcoat layer comprises the compound.

In some embodiments, the at least one ultraviolet laser comprises at least one lens having a focal length less than the distance between the point at which the at least one laser beam enters the transparent conductive film and the point at which the at least one laser beam enters the second conductive layer. In some embodiments, the first conductive layer comprises a first dye activated photo-acid having a first absorption wavelength and the second conductive layer comprises a second dye activated photo-acid having a second absorption wavelength, the first absorption wavelength being different from the second absorption wavelength, and wherein the first conductive layer is irradiated with the at least one ultraviolet laser at a first irradiation wavelength and the second conductive layer is irradiated with the at least one ultraviolet laser at a second irradiation wavelength, the first irradiation wavelength being different from the second irradiation wavelength.

In some embodiments, a substantial number of the first set of conductive nanostructures in the first conductive layer is aligned in a first direction and a substantial number of the second set of conductive nanostructures in the second conductive layer is aligned in a second direction, the first direction and second direction being substantially perpendicular to each other. In some embodiments, the first conductive layer or the second conductive layer is irradiated with a laser beam from the at least ultraviolet laser at a propagation direction having a propagation angle between about 1 and 89 degrees between the substrate and the laser beam.

In some embodiments, the first set of conductive nanostructures and the second set of conductive nanostructures each comprise silver nanowires. In some embodiments, the substrate comprises glass. In some embodiments, forming at least one pattern comprises irradiating the second conductive layer using the at least one laser to form a second pattern on the second conductive layer without forming the second pattern on the first conductive layer.

In some embodiments, a method is disclosed as comprising forming at least one pattern on a transparent conductive film comprising a substrate having a first side and a second side being opposite the first side, a first conductive layer positioned on the first side of the substrate and comprising a first set of metal nanostructures, a second conductive layer positioned on the second side of the substrate and comprising a second set of metal nanostructures, wherein the transparent conductive film comprises a radiation absorbing compound for reducing transmission of radiation through the substrate, wherein forming at least one pattern comprises irradiating the first conductive layer to form a first pattern on the first conductive layer without forming the first pattern on the second conductive layer.

In some embodiments, forming at least one pattern comprises irradiating the second conductive layer to form a second pattern on the second conductive layer without forming the second pattern on the first conductive layer.

### DESCRIPTION OF FIGURES

FIG. 1 shows a scanning electron micrograph of a laser pattern on dual sided silver nanowire coating at 1000×, where the vertical line is isolating, while the horizontal line is not isolating.

### DESCRIPTION

All publications, patents, and patent documents referred to in this document are incorporated by reference herein in their entirety, as though individually incorporated by reference.

U.S. Provisional Application No. 61/982,399, filed Apr. 22, 2014, entitled “LASER PATTERNING OF DUAL SIDED TRANSPARENT CONDUCTIVE FILMS,” is hereby incorporated by reference in its entirety.

A transparent conductive film may comprise a transparent conductive layer disposed on a substrate. The transparent conductive layer may comprise electrically conductive structures. Such a transparent conductive film may be patterned to produce regions of different conductivities. In some embodiments, a region that is patterned may become electrically isolating. In some cases, a transparent conductive film may comprise a first transparent conductive layer disposed on a first side of a substrate and a second transparent conductive layer disposed on a second side of the substrate that is opposite of the first side. The first transparent conductive layer and the second transparent conductive layer may comprise a first set of electrically conductive structures and a second set of electrically conductive structures, respectively. In such cases, the first transparent conductive layer and the second transparent conductive layer may each be patterned to form the same or different circuit layout or pattern. In some cases, patterning the first transparent conductive layer may cause undesired isolation of or damage to the second transparent conductive layer, and vice versa. Because the transparent conductive film is “transparent,” laser light that is intended to isolate the first transparent conductive layer may transmit through the substrate and isolate and/or damage the second transparent conductive layer. A method is disclosed herein for reducing the effects of patterning the first transparent conductive layer on the second transparent conductive layer.

The transparent conductive film may be substantially transparent, exhibiting at least about 90% total visible light transmission. The substrate may comprise a substantially transparent material, such as polyethylene terephthalate (PET), polyethylene (PE), cyclic olefin copolymer (COC), cyclic olefin polymer (COP), polycarbonate (PC), glass, or the like. Electrically conductive structures may include without limitation electrically conductive microstructures or electrically conductive nanostructures. Microstructures and nanostructures are defined according to the length of their shortest dimensions. The shortest dimension of the nanostructure is sized between 1 nm and 100 nm. The shortest dimension of the microstructure is sized between 0.1 μm to 100 μm. Conductive nanostructures may include, for example, metal nanostructures or other highly anisotropic nanoparticles. Non-limiting examples of electrically conductive nanostructures that may be incorporated into the electrically conductive layer include nanowires, nanotubes (e.g. carbon nanotubes), metal meshes, graphenes, and oxides, such indium tin oxide. Such electrically conductive nanostructures may comprise metals, such as silver or copper. For example, the electrically conductive nanostructures may be silver nanowires or copper nanowires. Examples of transparent conductive films comprising silver nanowires and methods for preparing them are disclosed in US patent application publication 2012/0107600, entitled “TRANSPARENT CONDUCTIVE FILM COMPRISING CELLULOSE ESTERS,” which is hereby incorporated by reference in its entirety.

### Laser Patterning

A method of patterning a transparent conductive film having conductive layers disposed on opposite sides of a substrate may involve the use of a laser, such as an ultraviolet laser. In such cases, the laser beam from the laser may transmit from a first conductive layer through the substrate to a second conductive layer, causing undesirable isolation of the second conductive layer. This application discloses various methods of reducing transmission of the laser beam through the substrate.

In some embodiments, a first conductive layer may be patterned using a laser that emits a laser beam that propagates at an angle that is non-orthogonal to the substrate. In such cases, the angle of propagation of the laser beam may be from about 1 degree to about 89 degrees relative to the substrate. Without wishing to be bound by theory, it is believed that a laser beam at an angle of propagation that is non-orthogonal to the substrate must travel a greater distance through the substrate, such that less of the laser beam for patterning the first conductive layer will reach the second conductive layer.

In some embodiments, the transparent conductive film may comprise a compound for reducing laser beam transmission through the substrate. The compound may correspond to the wavelength of the laser beam. The compound may comprise a radiation absorbing compound, such as an ultraviolet radiation absorbing compound to absorb the ultraviolet radiation. The compound may comprise a radiation absorbing compound, such as an infrared radiation absorbing compound to absorb the infrared radiation. Non-limiting examples of ultraviolet radiation absorbing compounds include metal oxides, such as ZnO, TiO₂, CeO₂, SnO₂, In₂O₃, and Sb₂O₃. Non-limiting examples of ultraviolet radiation absorbing compounds include compositions comprising benzophenone, benzotriazole (e.g.), cyanoacrylate, diethylamino hydroxybenzoyl hexyl benzoate, ethylhexyl triazone, oxybenzone, octinoxte, octocrylene, polyethylene glycol, aminobenzoic acid, sulisobenzone, sulisobenzone sodium, and sterically hindered amines (monomeric or oligomeric). Non-limiting examples of benzophenones include 2,2,′,4,4′-tetrahydroxylbenzophenone; 2,2,-dihydroxy-4,4-dimethoxybenzophenone; 2-hydroxy-4-octyloxybenzophenone; 2-hydroxy-4-methoxybenzophenone; and 2,4-dihydroxybenzophenone. Non-limiting examples of benzotriazoles include 6-tert-butyl-2-(5-chloro-2H-benzotriazole-2-yl)-4-methylphenol; 2,4-di-tert-butyl-6-(5-chloro-2H-benzotriazole-2yl)-phenol; 2-(2H-benzotriazole-2-yl)-4,6-di-tert-pentylphenol; 2-(2H-benzotriazole-2-yl)-4-(1,1,3,3-tetramethylbutyl)-phenol; 2-(2H-benzotriazole-2-yl)-4-methylphenol; and 2-(2H-benzotriazole-2yl)-4,6-bis(1-methyl-1-phenylethyl)phenol. Non-limiting examples of cyanoacrylate includes 1,3bis-[(2′-cyano-3′,3′-diphenylacryloyl)oxy]-2,2,-bis-{[(2′-cyano-3′,3′-diphenylacryloyl)oxy]methyl}-propane; ethyl-2-cyano-3,3,-diphenylacrylate and (2-ethylhexyl)-2-cyano-3,3,-diphenylacrylate. Non-limiting examples of sterically hindered amines (monomeric) include N,N′-bisformyl-N,N′-bis-(2,2,6,6,-tetramethyl-4-piperidinyl)-hexamethylendiamine; bis-(2,2,6,6-tetramethyl-4-piperidyl)-sebacate; and bis-(1,2,2,6,6-pentamethyl-4-piperidyl)-sebacate+methyl-(1,2,2,6,6,-pentamethyl-4-piperidyl)-sebacate. Other examples of ultraviolet absorbers include 2-ethylhexyl-p-methoxycinnamate. Such ultraviolet absorbers may be available under the tradename UVINUL® through the BASF Chemical Company. Additional examples of ultraviolet absorbers include hydroxyphenyl-benzotriazole, triazine, hydroxyphenyl-triazine also available under the trade name Tinuvin® through the BASF Chemical Company.

Non-limiting examples of infrared absorbers include cyanine dyes, quinones, metal complexes, photochrome dyes, squaraine dyes, metal dithiolene complexes, and diiminium compounds. The compound may comprise a dye activated photo-acid. In some embodiments, an undercoating compound may comprise a reflective compound, such as an ultraviolet reflective compound to reflect ultraviolet radiation or an infrared reflective compound to reflect infrared radiation. The reflective compound may protect the second conductive layer from isolation while the first conductive layer may receive the laser beam twice. The ultraviolet radiation absorbing compound or the ultraviolet radiation reflective compound may absorb or reflect laser beam at a wavelength below about 400 nm, such as about 355 nm.

The radiation absorbing or reflective compound (e.g. ultraviolet sensitive) may absorb or reflect at least about 1%, at least about 5%, at least about 10%, at least about 25%, or at least about 50% of the laser beam (e.g. ultraviolet laser beam). Even a small amount can effectively double or triple the processing window where one side will be isolated and the other will be unaffected. With the use of a compound, transmission of radiation through the transparent conductive film in the narrow wavelength range of interest may be reduced to less than about 90%, less than about 75%, or less than about 50%. In a double-sided film with a first conductive layer having a first conductivity and a second conductive layer having a second conductivity that comprises a radiation absorbing or reflective compound, subjecting the first conductive layer with radiation may cause substantial change in the conductivity of the first conductive layer while causing slight or no change in conductivity in the second conductive layer, such that the conductivity change of the second conductive layer is within 20%, 15%, 10%, 5%, or 1% of the second conductivity.

Such compounds may be added to at least one of the substrate, the first conductive layer, the second conductive layer, or additional layers. The transparent conductive film may comprise at least one first undercoat layer disposed on the first side of the substrate between the first conductive layer and the substrate, and the at least one first undercoat layer may comprise the compound. The transparent conductive film may comprise at least one second undercoat layer disposed on the second side of the substrate between the second conductive layer and the substrate, and the at least one second undercoat layer may comprise the compound. In some embodiments, the first conductive layer or the at least one first undercoat layer may comprise a first radiation absorbing compound having a first absorption wavelength and the second conductive layer or the at least one second undercoat layer may comprise a second radiation absorbing compound having a second absorption wavelength, where the first absorption wavelength is different from the second absorption wavelength. In such cases, the first absorption wavelength may correspond to the first laser wavelength being used to irradiate the first conductive layer or the at least one first undercoat layer and the second absorption wavelength may correspond to the second laser wavelength being used to irradiate the second conductive layer or the at least one second undercoat layer.

In some embodiments where the first conducive layer is patterned by a laser, the laser may comprise at least one lens having a focal length less than the distance between the point at which the laser beam enters the transparent conductive film and the point at which the laser beam enters the second conductive layer. The distance may correspond to the combined thickness of the layers disposed between the point at which the laser beam enters the transparent conductive film and the point at which the laser beam enters the second conductive layer. These layers may include a first conductive layer, the substrate, the second conductive layer, and optional layers, such as at least one first undercoat layer, at least one second undercoat layer, at least one first overcoat layer, and at least one second overcoat layer. Without wishing to be bound by theory, it is believed that a laser having at least one lens of a focal length less than the distance between the point at which the laser beam enters the transparent conductive film and the point at which the laser enters the second conductive layer may yield a laser beam that is defocused on the second side of the substrate, that is, the power intensity of the laser beam decreases by the time the laser beam exits the second side of the substrate to a level that does not isolate the second conductive layer.

In some embodiments where the electrically conductive structures are silver nanowires, the silver nanowires in the first conductive layer may be generally aligned in a first direction and the silver nanowires in the second conductive layer may be generally aligned in a second direction, the first direction and the second direction being substantially perpendicular. For anisotropic coatings, this may reduce the resistivity or minimum trace width in the preferred direction for a given pattern. In some embodiments, the silver nanowires in the first conductive layer may be preferentially aligned in the same direction as the silver nanowires in the second conductive layer. This may improve the ability to coat the top and bottom side of the substrate simultaneously and in a high-throughput roll-to-roll process. In some embodiments, the silver nanowires in the first and second conductive layers may be more or less randomly aligned and result in very little anisotropy in the conductivity when comparing the machine direction to the transverse direction of a coater.

Examples of laser parameters that may be used to pattern conductive layers on opposite sides of a substrate are disclosed in U.S. provisional patent application No. 61/931,831, filed Jan. 27, 2014, entitled POLARIZED LASER FOR PATTERNING OF NANOWIRE TRANSPARENT CONDUCTIVE FILMS, the contents of which are hereby incorporated by reference in its entirety herein. The laser used in patterning may be a polarized ultraviolet laser emitting light at an ultraviolet wavelength and pulse duration on the order of less than or equal to about 100 picoseconds, less than about 20 picoseconds, or less than about 10 picoseconds. Such a laser may render desired regions of the electrically conductive film electrically isolating with minimal damage to the polymer matrix in which the electrically conductive nanostructures are embedded and polymer layers over lying and underlying the electrically conductive layer. Such a laser may form the desired electrical pattern that is invisible to the unaided eye. For the purposes of this application, “minimal damage” may be interpreted to mean damage that does not substantially affect the function of the electrically conductive film. In some cases, damage is reduced to the point of not being discernible by the unaided eye.

The laser may be any suitable laser, for example, an excimer laser, a solid-state laser, such as a diode-pumped solid state laser, a semiconductor laser, a gas laser, a chemical laser, a fiber laser, a dye laser, or a free electron laser. The pulse duration of the laser may be on the order of nanoseconds, picoseconds, or femtoseconds. The electrically conductive film or the electrically conductive nanostructures may exhibit absorption across a wide spectrum of wavelengths and may accommodate a variety of lasers at different wavelengths. The laser may be an ultraviolet, visible, or an infrared laser. The laser may be a continuous wave laser or a pulsed laser. The laser may be operated at a selected scan speed, repetition rate, pulse energy, and laser power.

Where nanowires intersect, there may be an increase in radiation absorption in nanowires near the intersection. In some cases, such increase in absorption may be attributed to an increase in electric field or optical intensity near the intersection. Additionally, localized surface plasmon resonances (LSPR) may be more readily excited at the ends of the nanowires than the body of the nanowire although both are possible. It is believed that the combination of such characteristics of nanowires and laser process conditions may affect the amount and morphology of damage to the polymeric material surrounding the nanowires.

In some embodiments, the laser used in patterning may be an ultraviolet (UV) laser. UV lasers may emit light at wavelengths of up to about 450 nm. In some embodiments, an electrically conductive film is patterned with a laser emitting light at a wavelength of about 355 nm. Without wishing to be bound by theory, based on the Mie theory of light scattering, it is believed that Silver nanowires of 40 nm diameter and infinite length surrounded by cellulose acetate butyrate may have maximum radiation absorption at a wavelength of about 350-400 nm. In some embodiments, the laser used in patterning may be an infrared (IR) laser. IR lasers may emit light at wavelengths between about 650 nm to about 1 mm. In some embodiments, the laser used in patterning may be a visible laser. Visible lasers may emit light at wavelengths of about 350 nm to about 750 nm.

In some embodiments, the laser used in patterning may be polarized. Radiation, such as light, that exhibits different properties in different directions that are at right angles to the line of propagation is said to be polarized. Polarization of light may be described by specifying the orientation of the wave's electric field at a point in space over one period of oscillation. The direction of polarization may be described as the direction in which the wave oscillates. A laser beam may have a linear, circular, random, or radial polarization state. In linear polarization, the electric field oscillates in a certain stable direction perpendicular to the line of propagation of the laser beam. The laser beam may have a horizontal linear polarization state or a vertical linear polarization state. In circular polarization, the electric field may rotate as the wave travels. The laser beam may have a left circular polarization state or a right circular polarization state. In radial polarization, the electric field may have both a longitudinal and transverse component. In some cases, the electric field vector points toward the center of the beam at every position in the beam. In some cases, the electric field vector points radially outward.

Increased radiation absorption (e.g. maximized radiation absorption) by electrically conductive nanostructures may depend on the orientation of the pattern relative to the orientation of the polarization direction. In some embodiments, where a UV laser beam has a linear polarization direction in a first direction, less power per unit area is required to isolate a pattern aligned substantially in the first direction than a pattern aligned in a second direction that is substantially perpendicular to the first direction. For example, a random network of Silver nanowires with uniform orientation distribution may be in the XY plane, and a linearly polarized UV laser beam at 355 nm may be incident normal to the XY plane (i.e. propagating in the Z axis) with polarization aligned with the X direction. In such cases, less power per unit area may be required to isolate a pattern aligned in the X direction than a pattern aligned in the Y direction, which is perpendicular to the X and Z directions. Without wishing to be bound by theory, it is believed that a Surface Plasmon Resonance (SPR) may be generated preferentially in wires primarily aligned in the Y axis. The SPR may cause increased energy absorption in the wires oriented in the Y axis, which may tend to heat up and melt with less energy relative to wires that are not aligned with a significant component in the Y-axis. Mathematically, absorption at this wavelength has a component from the SPR which is related to the sine of the angle between the wire orientation and the direction of polarization such that when the angle is zero the SPR is zero, but when the angle is 90 degrees, the SPR is at its maximum. Through this mechanism, when the UV laser is polarized in the X direction, a line patterned in the X direction may require lower energy relative to a line patterned in the Y direction. The X direction line may have wires oriented in the Y direction, which may be situated across the isolation path, preferentially melted. Conversely, the Y direction line may tend to melt wires parallel to the isolation path, but may leave the wires that span across the gap in the X direction, which may leave an electrical path between the two regions so electrical current can flow between the two regions, and thus, require more energy to become isolated. Increased radiation absorption (e.g. maximized radiation absorption) by electrically conductive nanostructures may depend on the orientation of the nanostructures relative to the polarization direction of the radiation source and the wavelength of the radiation source. In some embodiments, electrically conductive nanostructures aligned parallel with the polarization direction of a laser beam may exhibit increased radiation absorption from lasers outputting wavelengths longer than about 400 nm or longer than about 500 nm, such as an infrared or visible laser. An infrared laser has an output wavelength in the infrared region of the electromagnetic spectrum, that is, wavelength in the range from about 750 nm to about 1 mm. A visible laser has an output wavelength in the visible region of the electromagnetic spectrum, that is, wavelength in the range from about 400 nm to about 750 nm. In some cases, electrically conductive nanostructures aligned parallel with the polarization direction of an infrared laser beam may exhibit increased radiation absorption at approximately 1064 nm. In such cases, electrically conductive nanostructures aligned parallel with the polarization direction of a visible laser may exhibit increased radiation absorption at approximately 532 nm. In some embodiments, electrically conductive nanostructures aligned perpendicular to the polarization direction of a laser beam may exhibit increased radiation absorption from an ultraviolet laser. An ultraviolet laser has an output wavelength in the ultraviolet region of the electromagnetic spectrum, that is, wavelength in the range from about 10 nm to about 400 nm. In such cases, electrically conductive nanostructures aligned perpendicular to the polarization direction of an ultraviolet laser may exhibit increased radiation absorption at approximately 355 nm.

In some embodiments, the electrically conductive nanostructure in the transparent conductive film may be a plurality of silver nanowires. For silver nanowires, the SPR peak in absorption when light is polarized perpendicular to the wires occurs at between 350 to 400 nm. In this case, the transverse electric (TE) component of absorption dominates at wavelengths shorter than about 500 nm and above 500 nm the transverse magnetic (TM) absorption—where the electric field is polarized parallel to the wire—dominates. Total absorption for a randomly aligned network will be the average of TE and TM absorption. Thus, for silver nanowires, the threshold wavelength where the dominating absorption polarization changes from TE to TM is about 500 nm. In other metallic nanowire films, the SPR peak may be at shorter or longer wavelengths. For example, a random network of gold nanowires may have the SPR peak in the visible wavelength range and the threshold wavelength where the dominating absorption polarization changes from TE to TM may be in the range of 600-1000 nm or 500 to 1500 nm, etc.

In some embodiments, where an infrared or visible laser beam has a linear polarization direction in a first direction, more power per unit area is required to isolate a pattern aligned substantially in the first direction than a pattern aligned in a second direction that is substantially perpendicular to the first direction. For example, a random network of metallic nanowires with uniform orientation distribution may be in the XY plane, and a linearly polarized infrared or visible laser beam may be incident normal to the XY plane (i.e. propagating in the Z axis) with polarization aligned with the X direction. In such cases, less power per unit area may be required to isolate a pattern aligned in the Y direction than a pattern aligned in the X direction, which is perpendicular to the Y and Z directions. Without wishing to be bound by theory, it is believed that wires primarily aligned in the X axis have increased absorption. The increased energy absorption in the wires oriented in the X axis may tend to heat up and melt with less energy relative to wires that are not aligned with a significant component in the X-axis. Mathematically, absorption at this wavelength has a component related to polarization which is related to the cosine of the angle between the wire orientation and the direction of polarization such that when the angle is zero the absorption is maximum, but when the angle is 90 degrees, the absorption is at its minimum or zero. Through this mechanism, when the IR or visible laser is polarized in the X direction, a line patterned in the Y direction may require lower energy relative to a line patterned in the X direction. The Y direction line may have wires oriented in the X direction, which may be situated across the isolation path, preferentially melted. Conversely, the X direction line may tend to melt wires parallel to the isolation path, but may leave the wires that span across the gap in the Y direction, which may leave an electrical path between the two regions so electrical current can flow between the two regions, and thus, require more energy to become isolated.

In some embodiments, an electrically conductive film may comprise randomly oriented electrically conductive nanostructures some of which may align parallel with the direction of polarization of a laser beam, some of which may align perpendicular with the direction of polarization of the laser beam, and others which may have a component that is parallel and a component that perpendicular to the direction of polarization. In some cases, an infrared or visible laser may ablate electrically conductive nanostructures aligned parallel with the direction of polarization of a laser beam to attain electrical isolation while other oriented electrically conductive nanostructures remain un-ablated for minimal change in optical properties, which may make the pattern more invisible to the unaided eye. In some cases, an ultraviolet laser may ablate electrically conductive nanostructures aligned perpendicular with the direction of polarization of a laser beam to attain electrical isolation while other oriented electrically conductive nanostructures remain un-ablated for minimal change in optical properties, which may make the pattern more invisible to the unaided eye.

### EXEMPLARY EMBODIMENTS

U.S. Provisional Application No. 61/982,399, filed Apr. 22, 2014, entitled “LASER PATTERNING OF DUAL SIDED TRANSPARENT CONDUCTIVE FILMS,” which is hereby incorporated by reference in its entirety, disclosed the following 59 exemplary non-limiting embodiments:

A. A method of patterning an unpatterned transparent conductive film,

the unpatterned transparent conductive film comprising: a transparent substrate, a first conductive layer disposed on a first surface of the transparent substrate, and a second conductive layer disposed on a second surface of the transparent substrate, the first and second surfaces being disposed on two opposing sides of the unpatterned transparent conductive film, the first conductive layer comprising a first set of metal nanostructures, and the second conductive layer comprising a second set of metal nanostructures,

the method comprising:

irradiating the first conductive layer with at least one first laser to form a patterned transparent conductive film,

wherein the irradiation of the first conductive layer patterns the first conductive layer with a first pattern without also patterning the second conductive layer with the first pattern, and

further wherein the unpatterned transparent conductive film and the patterned transparent conductive film both exhibit total visible light transmissions of at least about 90%.

B. The method according to embodiment A, wherein the unpatterned transparent conductive film further comprises at least one radiation reflecting compound or at least one radiation absorbing compound.
C. The method according to embodiment A, wherein the transparent substrate further comprises at least one radiation reflecting compound or at least one radiation absorbing compound.
D. The method according to embodiment A, wherein the first conductive layer further comprises at least one radiation reflecting compound or at least one radiation absorbing compound.
E. The method according to embodiment A, wherein the second conductive layer further comprises at least one radiation reflecting compound or at least one radiation absorbing compound.
F. The method according to embodiment A, wherein the unpatterned transparent conductive film further comprises at least one ultraviolet radiation reflecting compound or at least one ultraviolet radiation absorbing compound
G. The method according to embodiment A, wherein the transparent substrate further comprises at least one ultraviolet radiation reflecting compound or at least one ultraviolet radiation absorbing compound.
H. The method according to embodiment A, wherein the first conductive layer further comprises at least one ultraviolet radiation reflecting compound or at least one ultraviolet radiation absorbing compound.
J. The method according to embodiment A, wherein the second conductive layer further comprises at least one ultraviolet radiation reflecting compound or at least one ultraviolet radiation absorbing compound.
K. The method according to embodiment A, wherein the unpatterned transparent conductive film further comprises at least one infrared radiation reflecting compound or at least one infrared radiation absorbing compound.
L. The method according to embodiment A, wherein the transparent substrate further comprises at least one infrared radiation reflecting compound or at least one infrared radiation absorbing compound.
M. The method according to embodiment A, wherein the first conductive layer further comprises at least one infrared radiation reflecting compound or at least one infrared radiation absorbing compound.
N. The method according to embodiment A, wherein the second conductive layer further comprises at least one infrared radiation reflecting compound or at least one infrared radiation absorbing compound.
P. The method according to embodiment A, wherein the transparent conductive film further comprises at least one first undercoat layer disposed between the first conductive layer and the transparent substrate, and at least one second undercoat layer disposed between the second conductive layer and the transparent substrate.
Q. The method according to embodiment P, wherein at least one of the at least one first undercoat layer and the second undercoat layer further comprises at least one radiation reflecting compound or at least one radiation absorbing compound.
R. The method according to embodiment P, wherein at least one of the at least one first undercoat layer and the second undercoat layer further comprises at least one ultraviolet radiation reflecting compound or at least one ultraviolet radiation absorbing compound.
S. The method according to embodiment P, wherein at least one of the at least one first undercoat layer and the second undercoat layer further comprises at least one infrared radiation reflecting compound or at least one infrared radiation absorbing compound.
T. The method according to any of embodiments A-S, wherein the first set of metal nanostructures comprises silver nanowires.
U. The method according to any of embodiments A-T, wherein the second set of metal nanostructures comprises silver nanowires.
V. The method according to any of embodiments A-U, wherein the transparent substrate comprises glass.
W. The method according to any of embodiments A-V, wherein the at least one first laser emits at least one first laser beam that is linearly polarized.
X. The method according to any of embodiments A-W, wherein the irradiation of the first conductive layer comprises emitting at least one first laser beam having a pulse duration less than about 100 picoseconds.
Y. The method according to any of embodiments A-X, wherein the irradiation of the first conductive layer comprises emitting at least one first laser beam having a pulse duration less than about 50 picoseconds.
Z. The method according to any of embodiments A-Z, wherein the irradiation of the first conductive layer comprises emitting at least one first laser beam having a pulse duration less than about 20 picoseconds.
AA. The method according to any of embodiments A-Z, further comprising irradiating the second conductive layer with at least one second laser.
AB. The method according to embodiment AA, wherein the irradiation of the first conductive layer comprises emitting at least one first laser beam comprising a first wavelength, and further wherein the irradiation of the second conductive layer comprises emitting at least one second laser beam comprising a second wavelength, the first wavelength and the second wavelength being substantially the same.
AC. The method according to embodiment AA, wherein the irradiation of the first conductive layer comprises emitting at least one first laser beam comprising a first wavelength, and further wherein the irradiation of the second conductive layer comprises emitting at least one second laser beam comprising a second wavelength, the first wavelength and the second wavelength being substantially different.
AD. The method according to AA, wherein the irradiating the second conductive layer comprises emitting at least one second laser beam having a propagation angle between about 1 and about 89 degrees between the substrate and the at least one second laser beam.
AE. The method according to any of embodiments AA-AD, wherein the at least one first laser and the at least one second laser comprise one or more lasers in common.
AF. The method according to any of embodiments AA-AE, wherein the first conductive layer and the second conductive layer are irradiated simultaneously.
AG. The method according to any of embodiments AA-AF, wherein the irradiation of the second conductive layer patterns the second conductive layer with a second pattern without also patterning the first conductive layer with the second pattern.
AH. The method according to any of embodiments A-AG, wherein the at least one first laser emits at least one first laser beam that has an ultraviolet wavelength.
AJ. The method according to any of embodiments A-AH, wherein the transparent conductive film exhibits ultraviolet radiation transmission less than about 90%.
AK. The method according to any of embodiments A-AJ, wherein the transparent conductive film exhibits ultraviolet radiation transmission less than about 75%.
AL. The method according to any of embodiments A-AK, wherein the transparent conductive film exhibits ultraviolet radiation transmission less than about 50%.
AM. The method according to any of embodiments A-AL, wherein the irradiating the first conductive layer comprises emitting at least one first laser beam having a propagation angle between about 1 and about 89 degrees between the substrate and the at least one second laser beam.
AN. A transparent conductive film comprising:
a transparent substrate comprising a first surface and a second surface on opposing sides of the transparent substrate;
at least one first conductive layer disposed on the first surface, the at least one first conductive layer comprising a first set of metal nanostructures;
at least one second conductive layer disposed on the second surface, the at least one second conductive layer comprising a second set of metal nanostructures; and
at least one compound comprising at least one radiation reflecting compound or at least one radiation absorbing compound,
wherein the transparent conductive film exhibits total visible light transmission of at least about 90%.
   38. The transparent conductive film according to embodiment AN, wherein the at least one compound comprises at least one radiation reflecting compound.
   39. The transparent conductive film according to embodiment 38, wherein the at least one radiation reflecting compound comprises at least one ultraviolet reflecting compound.
   40. The transparent conductive film according to embodiment 39, wherein the at least one radiation reflecting compound comprises at least one infrared reflecting compound.
   41. The transparent conductive film according to embodiment AN, wherein the at least one compound comprises at least one radiation absorbing compound.
   42. The transparent conductive film according to embodiment 41, wherein the at least one radiation absorbing compound comprises at least one ultraviolet absorbing compound.
   43. The transparent conductive film according to embodiment 41, wherein the at least one radiation absorbing compound comprises at least one infrared absorbing compound.
   44. The transparent conductive film according to any of embodiments AN-43, wherein the transparent substrate comprises the at least one compound.
   45. The transparent conductive film according to any of embodiments AN-44, wherein the at least one first conductive layer comprises the at least one compound.
   46. The transparent conductive film according to any of embodiments AN-45, wherein the at least one second conductive layer comprises the at least one compound.
   47. The transparent conductive film according to any of embodiments AN-47, further comprising at least one first undercoat layer disposed between the at least one first conductive layer and the transparent substrate.
   48. The transparent conductive film according to embodiment 47, wherein the at least one first undercoat layer comprises the at least one compound.
   49. The transparent conductive film according to any of embodiments AN-48, further comprising at least one second undercoat layer disposed between the at least one first conductive layer and the transparent substrate.
   50. The transparent conductive film according to embodiment 49, wherein the at least one second undercoat layer comprises the at least one compound.
   51. The transparent conductive film according to any of embodiments AN-50, wherein the first set of metal nanostructures comprises silver nanowires.
   52. The transparent conductive film according to any of embodiments AN-51, wherein the second set of metal nanostructures comprises silver nanowires.
   53. The transparent conductive film according to any of embodiments AN-52, wherein the transparent substrate comprises glass.
   54. The transparent conductive film according to any of embodiments AN-53, wherein the transparent conductive film exhibits ultraviolet radiation transmission less than about 90%.
   55. The transparent conductive film according to any of embodiments AN-54, wherein the transparent conductive film exhibits ultraviolet radiation transmission less than about 75%.
   56. The transparent conductive film according to any of embodiments AN-55, wherein the transparent conductive film exhibits ultraviolet radiation transmission less than about 50%.
   57. The transparent conductive film according to any of embodiments AN-56, wherein the at least one first conductive layer is patterned with a first pattern.
   58. The transparent conductive film according to embodiment 57, wherein the at least one second conductive layer is patterned with a second pattern.
   59. The transparent conductive film according to embodiment 58, wherein the first pattern and the second pattern are not the same.

### EXAMPLES

### Example 1

A UV laser was used to produce an isolation test pattern of square boxes that overlap at the corners, similar to a tic-tac-toe shape, on a double-sided transparent conductive film. The film comprised of a first overcoat layer disposed on the first silver nanowire layer, which is positioned on a first side of a PET substrate, a second silver nanowire layer positioned on a second side of the PET substrate that is opposite the first side, and a second overcoat layer disposed on the second silver nanowire layer. Both silver nanowire layers had nominally 100Ω/□ sheet resistance and were disposed on a 125 μm thick PET base. The UV laser was linearly polarized with a polarization ratio of 100:1. The laser pulse duration was in the nanosecond regime. The laser had a repetition rate of 200 kHz and 1000 mm/s with a spot size of about 20 microns. The average power of the laser was varied in increments of about 10 mW. A laser beam from the UV laser was directed at the substrate from the top side. This example generally demonstrates that more power is required to isolate the bottom side when the laser beam is directed at the top side and must pass through the first overcoat layer, first silver nanowire layer, and substrate before reaching the second silver nanowire layer, as shown in TABLE 1.

TABLE 1

| | Power (W) | Power (W) |
|---|---|---|
| | to Isolate | to Isolate |
| Sample | Top Side | Bottom Side |
| 1 | 0.23 | 0.27 |
| 2 | 0.20 | 0.32 |
| 3 | 0.21 | 0.31 |
| 4 | 0.21 | 0.28 |
| 5 | 0.20 | 0.27 |
| 6 | 0.20 | 0.32 |

### Example 2

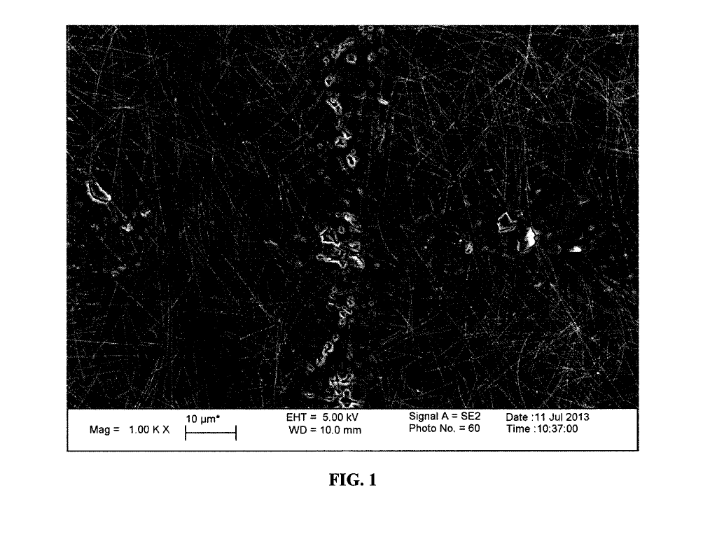

A UV laser was used to produce an isolation test pattern of bar and stripes on a double-sided transparent conductive film. The film comprised of a first overcoat layer disposed on the first silver nanowire layer, which is positioned on a first side of a PET substrate, a second silver nanowire layer positioned on a second side of the PET substrate that is opposite the first side, and a second overcoat layer disposed on the second silver nanowire layer. The UV laser was linearly polarized with a polarization ratio of 100:1. The laser pulse duration was in the nanosecond regime. The laser had a repetition rate of 75 kHz and 750 mm/s with a spot size of about 20 microns. A laser beam from the UV laser was directed at the substrate from the top side to produce a “bars” pattern with a power less than 0.23 W as determined in Example 1 to isolate the top side and minimize isolation of the bottom side. The conductive film was flipped over and aligned to a reference position. A laser beam from the UV laser was directed at the substrate from the bottom side to produce a “stripes” pattern as determined in Example 1 to isolate the bottom side and minimize isolation of the top side. The bars and stripes are generally oriented in a direction perpendicular to each other. FIG. 1 shows the film having a non-isolating vertical line on one side and an isolating horizontal line caused when patterning on the opposite side.

This example generally demonstrates that more power is required to isolate the bottom side when the laser beam is directed at the top side and must pass through the first overcoat layer, first silver nanowire layer, and substrate before reaching the second silver nanowire layer, as shown in TABLE 2. Note that the power to isolate the top and bottom side when not passing through the various layers and substrate is less than the minimum power required to isolate the bottom side when passing through the substrate, as shown in TABLE 1. Therefore, this example illustrates a potential manufacturing method for patterning dual-layer silver nanowire coatings to form a touch panel device.

TABLE 2

| | Power (W) | Power (W) |
|---|---|---|
| | to Isolate | to Isolate |
| Sample | Top Side | Bottom Side |
| 1 | 0.23 | 0.23 |
| 2 | 0.22 | 0.22 |
| 3 | 0.22 | 0.24 |
| 4 | 0.22 | 0.24 |
| 5 | 0.21 | 0.25 |
| 6 | 0.20 | 0.21 |

### Example 3

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The substrate comprises a UV radiation absorption compound. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser is directed at the substrate from the top side. We expect that more power is required to isolate either the first silver nanowire layer or the second silver nanowire layer from a laser beam passing through the second side or first side, respectively, and the substrate, as compared to Examples 1 and 2. In this example, the process window for isolating one side and not the other side is larger and gives more flexibility in a mass-production environment.

### Example 4

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first silver nanowire layer comprises a UV radiation absorption compound. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser is directed at the substrate from the top side. We expect that less power is required to isolate the first silver nanowire layer. Without wishing to be bound by theory, it is believed that the first silver nanowire layer will require less energy to isolate because it will absorb more energy because of the presence of the UV radiation absorption compound. Similarly, we expect that more power is required to isolate the second silver nanowire layer from a laser beam passing through the first side and substrate as compared to Examples 1 and 2. It is believed that by having the radiation absorption compound in the first silver nanowire layer that less energy will pass through to the second layer. Thus, the process window for isolating the first silver nanowire layer without isolating the second silver nanowire layer will be larger. However, if the second silver nanowire layer does not include the radiation absorbing compound, then the reverse scenario will not have the same process window. It is believed that in this example, the process window will be worse when directing the laser beam at the second silver nanowire layer to form an isolating pattern and wishing not to isolate the first silver nanowire layer, since the same amount of radiation will pass through the second silver nanowire layer and substrate and more energy will be absorbed by the first silver nanowire layer when compared to Examples 1 and 2.

### Example 5

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first and second silver nanowire layers both comprise a UV radiation absorption compound. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser was directed at the substrate from the top side. We expect that less power is required to isolate either the first silver nanowire layer or second silver nanowire layers when the laser beam does not pass through the second side or first side, respectively as compared to Examples 1 and 2. We expect that more power is required to isolate either the first silver nanowire layer or the second silver nanowire layer from a laser beam passing through the second side or first side, respectively, as compared to Examples 1 and 2. It is believed that by having a UV radiation absorbing compound in both the first and second silver nanowire layers that the process window for isolation of one side and not the other will be increased relative to Examples 1 and 2.

### Example 6

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The substrate comprises a UV radiation reflective compound. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser is directed at the substrate from the top side. We expect that more power is required to isolate either the first silver nanowire layer or the second silver nanowire layer from a laser beam passing through the second side or first side, respectively, as compared to Examples 1 and 2.

### Example 7

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first and second silver nanowire layers comprise a UV radiation reflective compound. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser is directed at the substrate from the top side. We expect that more power is required to isolate either the first silver nanowire layer or the second silver nanowire layer from a laser beam passing through the second side or first side, respectively, as compared to Examples 1 and 2.

### Example 8

### Prophetic

A UV laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The second silver nanowire layer comprises a UV radiation reflective and absorptive compound. Metallic nanostructures have enhanced absorption and scattering at wavelengths close to SPR peaks. As described above, in silver nanowire based TCFs, the SPR peak in absorption and scattering when light is polarized perpendicular to the wires occurs at between 350 and 400 nm. A double-sided transparent conductive film composed of silver nanowires with lower sheet resistance, such as 50Ω/□ or 30Ω/□, will include a greater amount of nanostructures per unit area compared to Examples 1 and 2. Therefore, it will have higher scattering and higher absorption in both silver nanowire layers when compared to Examples 1 and 2. The UV laser is linearly polarized with a polarization ratio of 100:1. The laser pulse duration is in the nanosecond regime. The laser has a repetition rate of 200 kHz and 1000 mm/s with a spot size of about 20 microns. The average power of the laser is varied in increments of about 10 mW. A laser beam from the UV laser is directed at the substrate from the top side. We expect that more power is required to isolate the first silver nanowire layer from a laser beam passing through the second silver nanowire layer, as compared to Examples 1 and 2. We expect less power is required to isolate the second silver nanowire layer from a laser beam that hits the second silver nanowire layer without passing through the first nanowire layer and the substrate.

### Example 9

### Prophetic

An IR laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The substrate comprises an IR radiation absorption compound. A laser beam from the IR laser is directed at the substrate from the top side. We expect that more power is required to isolate either the first silver nanowire layer or the second silver nanowire layer from a laser beam passing through the second side or first side, respectively, as compared to the case without the IR radiation absorbing compound in the substrate.

### Example 10

### Prophetic

An IR laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first silver nanowire layer comprises an IR radiation absorption compound. A laser beam from the IR laser is directed at the substrate from the top side. Without wishing to be bound by theory, it is believed that the first silver nanowire layer will require less energy to isolate because it will absorb more energy. Similarly, we expect that more power is required to isolate the second silver nanowire layer from a laser beam passing through the first side and substrate as compared to the case without the IR radiation absorbing compound in the first silver nanowire layer. It is believed that by having the radiation absorption compound in the first silver nanowire layer that less energy will pass through to the second layer. Thus the process window for isolating the first silver nanowire layer without isolating the second silver nanowire layer will be larger. However, if the second silver nanowire layer does not include the radiation absorbing compound, then the reverse scenario will not have the same process window. It is believed that in this example, the process window will be worse when directing the laser beam at the second silver nanowire layer to form an isolating pattern and wishing not to isolate the first silver nanowire layer, since the same amount of radiation will pass through the second silver nanowire layer and substrate and more energy will be absorbed by the first silver nanowire layer when compared to the case without the IR radiation absorbing compound in the first silver nanowire layer.

### Example 11

### Prophetic

An IR laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first and second silver nanowire layers comprise an IR radiation absorption compound. A laser beam from the IR laser is directed at the substrate from the top side. We expect that more power is required to isolate either the first silver nanowire layer or the second silver nanowire layer from a laser beam passing through the second side or first side, respectively, as compared to the case without the IR radiation absorbing compound in the first and second silver nanowire layers.

### Example 12

### Prophetic

An IR laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The substrate comprises an IR radiation reflective compound. A laser beam from the IR laser is directed at the substrate from the top side. We expect that more power is required to isolate either the first silver nanowire layer or the second silver nanowire layer from a laser beam passing through the second side or first side, respectively, as compared to the case without the IR radiation reflective compound in the substrate.

### Example 13

### Prophetic

An IR laser is used to produce an isolation pattern on a double-sided transparent conductive film. The film comprises a first overcoat layer disposed on the first silver nanowire layer, which is positioned on a first side of a substrate, a second silver nanowire layer positioned on a second side of the substrate that is opposite the first side, and a second overcoat layer disposed on the second silver nanowire layer. The first and second silver nanowire layers comprise an IR radiation reflective compound. A laser beam from the IR laser is directed at the substrate from the top side. We expect that more power is required to isolate either the first silver nanowire layer or the second silver nanowire layer from a laser beam passing through the second side or first side, respectively, as compared to the case without the IR radiation reflective compound in the first and second silver nanowire layers.

The invention has been described in detail with reference to specific embodiments, but it will be understood that variations and modifications can be effected within the spirit and scope of the invention. The presently disclosed embodiments are therefore considered in all respects to be illustrative and not restrictive. The scope of the invention is indicated by the attached claims, and all changes that come within the meaning and range of equivalents thereof are intended to be embraced therein.

What is claimed:

1. A method of patterning an unpatterned transparent conductive film,
the unpatterned transparent conductive film comprising: a transparent substrate, a first conductive layer disposed on a first surface of the transparent substrate, and a second conductive layer disposed on a second surface of the transparent substrate, the first and second surfaces being disposed on two opposing sides of the unpatterned transparent conductive film, the first conductive layer comprising a first set of metal nanostructures, and the second conductive layer comprising a second set of metal nanostructures,
the method comprising:
irradiating the first conductive layer with at least one first laser to form a patterned transparent conductive film,
wherein the irradiation of the first conductive layer patterns the first conductive layer with a first pattern without also patterning the second conductive layer with the first pattern, and
further wherein the unpatterned transparent conductive film and the patterned transparent conductive film both exhibit total visible light transmissions of at least about 90%.

2. The method according to claim 1, wherein the unpatterned transparent conductive film further comprises at least one radiation reflecting compound or at least one radiation absorbing compound.

3. The method according to claim 1, wherein the unpatterned transparent conductive film further comprises at least one ultraviolet radiation reflecting compound, at least one ultraviolet radiation absorbing compound, at least one infrared radiation reflecting compound, or at least one infrared radiation absorbing compound.

4. The method according to claim 1, wherein the transparent conductive film further comprises at least one first undercoat layer disposed between the first conductive layer and the transparent substrate, and at least one second undercoat layer disposed between the second conductive layer and the transparent substrate.

5. The method according to claim 1, wherein the first set of metal nanostructures comprises silver nanowires.

6. The method according to claim 5, wherein the second set of metal nanostructures comprises silver nanowires.

7. The method according to claim 1, wherein the at least one first laser emits at least one first laser beam that is linearly polarized.

8. The method according to claim 1, further comprising irradiating the second conductive layer with at least one second laser.

9. The method according to claim 8, wherein the irradiation of the first conductive layer comprises emitting at least one first laser beam comprising a first wavelength, and further wherein the irradiation of the second conductive layer comprises emitting at least one second laser beam comprising a second wavelength, the first wavelength and the second wavelength being substantially the same.

10. The method according to claim 8, wherein the irradiation of the first conductive layer comprises emitting at least one first laser beam comprising a first wavelength, and further wherein the irradiation of the second conductive layer comprises emitting at least one second laser beam comprising a second wavelength, the first wavelength and the second wavelength being substantially different.

11. The method according to claim 8, wherein the at least one first laser and the at least one second laser comprise one or more lasers in common.

12. The method according to claim 8, wherein the irradiation of the second conductive layer patterns the second conductive layer with a second pattern without also patterning the first conductive layer with the second pattern.

13. A transparent conductive film comprising:
a transparent substrate comprising a first surface and a second surface on opposing sides of the transparent substrate;
at least one first conductive layer disposed on the first surface, the at least one first conductive layer comprising a first set of metal nanostructures;
at least one second conductive layer disposed on the second surface, the at least one second conductive layer comprising a second set of metal nanostructures; and
at least one compound comprising at least one radiation reflecting compound or at least one radiation absorbing compound,
wherein the transparent conductive film exhibits total visible light transmission of at least about 90%

14. The transparent conductive film according to claim 13, further comprising at least one first undercoat layer disposed between the at least one first conductive layer and the transparent substrate.

15. The transparent conductive film according to claim 14, further comprising at least one second undercoat layer disposed between the at least one second conductive layer and the transparent substrate.

16. The transparent conductive film according to claim 13, wherein the at least one first conductive layer is patterned with a first pattern.

17. The transparent conductive film according to claim 16, wherein the at least one second conductive layer is patterned with a second pattern.

18. The transparent conductive film according to embodiment 17, wherein the first pattern and the second pattern are not the same.
